(19) United States
(12) Patent Application Publication
(10) Pub. No.: US 2008/0050517 A1
(43) Pub. Date: Feb. 28, 2008

(54) Pulse Heating Methods and Apparatus for Printing and Dyeing

(75) Inventors: William Grier, Highland, CA (US); Ronald Breitag, Fontana, CA (US); Van Schmelzer, Escondido, CA (US)

Correspondence Address: FISH & ASSOCIATES, PC;ROBERT D. FISH, 2603 Main Street, Suite 1050, Irvine, CA, 92614-6232, US

(73) Assignee: COLOREP, INC., Rancho Cucamonga, CA (US)

(21) Appl. No.: 11/844,180

(22) Filed: Aug. 23, 2007

Related U.S. Application Data
(60) Provisional application No. 60/839,956, filed on Aug. 23, 2006.

(51) Int. Cl. B05D 1/00; C23C 16/44

(52) U.S. Cl. 427/209; 118/725

(57) ABSTRACT

The present invention provides apparatus, systems and methods in which one or more dyes are placed on first and second donors, the donors are positioned on the opposite side of a receiver, and a burst of pulse energy is applied to the first donor at a temperature of at least 260° F. and a heat energy is applied to the receiver at a lower temperature. The pulse energy allows for more uniformed application of high energy dyes onto the receiver.

This application claims priority to U.S. provisional application Ser. No. 60/839,956 filed Aug. 23, 2006.

### FIELD OF THE INVENTION

The field of the invention is in sublimation printing and dyeing.

### BACKGROUND

Throughout the existence of mankind, humans have always found a way to decorate fabric with colors. Starting with hides and later woven and knitted materials, the traditional approach has been to liquefy the color by suspending it in a solution of water or some other fluid. The object to be dyed is then submersed in the solution or coated with it to produce the desired color.

Great skill was required to produce the desired color using this classic vat dyeing method. Great skill is still required to produce “dye lots” of the same color even with today's sophisticated equipment. Producing an exact color match is a product of re-creating the exact intersection of color concentration, energy (usually heat), object material, and processing time over and over in a chamber with constantly changing dynamics.

Skilled craftsmen all over the world dye over 25 million tons of polymer based fabric annually using derivatives of these ancient skills. This process produces tons of clothing, home fashion products, and the most water pollution in the world. As new sources of fiber (mostly polymer based) are developed, the application of these ancient skills has become more difficult and problematic. The net effect is the decrease of matching yields and the increase of energy use and the production of ever greater volumes of dangerous effluents.

One solution is to use an extension of dispersed dye sublimation technology (hereafter referred to as DDS). DDS printing has been used for decades to print images on various fabrics and other receiving materials. In that process an ink is printed onto a donor transfer paper, and the paper is juxtaposed against the receiving material. When heat is applied to the outside surface of the paper, the special dyes explode into dye laden superheated air and drive the colorant into the receiving material. This use of super heated air—not water—as the carrying agent dramatically reduces pollution and energy use. The use of DDS technology for dyeing fabric and other materials is not new; it has been attempted for years without success for a number of reasons.

The primary problem with DDS is that the process cannot deliver sufficient color saturation to replicate water based solution dyeing. The common approach historically has been to place donor paper on both sides of the receiver; this process has not provided sufficient saturation and color replication to replace solution dyeing. Failure to color knit fabric when stretched and failure to color threads that roll during sewing and cutting has made two-sided printing in current equipment commercially unsatisfactory. Another problem is in the temperature of the receiver as it enters into the process. Generally, conventional starting temperature of backside donors are between 140° to 170° F., which is not sufficient enough to provide a great saturation of dye coverage. Furthermore, not all dyes are sublimatable with DDS. High energy dyes while delivering stable brilliant colors require much higher temperature to phase change which can destroy the receiver during sublimation. Because of this and other problems, DDS has never been used commercially in place of dyeing to cover the majority of a face of a receiving material (e.g. printing of solids). The defect lines would simply be too obvious.

Another disadvantage of DDS printing is that double-sided printing yields colorations that are different from side to side even if the same ink is used. The reason is that the second application of heat tends to vaporize the first application of dye out of the paper and onto a take-up paper. See e.g. US 2003/0217685 to Mason et al. (pub. Nov. 27, 2003), and US 2003/0035675 to Emery at al. (pub. Feb. 20, 2003). These and all other publications referred to herein are incorporated by reference in their entirety.

Still another disadvantage of DDS printing is that it is entirely additive. Thus, if one prints a full color image on a yellow background, one must print over top of the yellow background, which distorts the colors of the image. Where multiple images or multiple passes are used, there can are also be significant registering problems. See e.g., U.S. Pat. No. 6,393,988 to Gaskin (May 28, 2002).

This and all other referenced patents and applications are incorporated herein by reference in their entirety. Where a definition or use of a term in a reference, which is incorporated by reference herein is inconsistent or contrary to the definition of that term provided herein, the definition of that term provided herein applies and the definition of that term in the reference does not apply.

Thus, there is still a need for sublimation techniques to print solids and other integrated designs penetrating both sides of fabrics and other receiving materials, with good color consistency and vastly improved consistent color saturation.

### SUMMARY OF THE INVENTION

The present invention provides apparatus, systems and methods in which one or more dyes are placed on multiple donors, positioning at least two donors on opposite sides of the receiver; applying a pulse of heat energy to the assembled donors and receiver, then reducing the energy to complete placing and fixing the dyes.

Preferably, the first donor is physically separated from the second donor. They can be on opposite sides of the receiver. Positioning of the first and second donors can be by hand placing or automatically placing.

The pulse of heat energy is calibrated, based on the weight and heat sync of the receiver, to be of duration only long enough to phase change the dye affixed to the donors. This pulse period is at least three seconds but may be longer based on the energy required to phase change different dyes and the mitigating factors of weight, fabric density and fiber heat sync.

In preferred embodiments, a sublimation process system accommodates a pulse heater and a pulse heating station to manufacture a fabric.

Various objects, features, aspects and advantages of the present invention will become more apparent from the following detailed description of preferred embodiments of the invention, along with the accompanying drawings in which like numerals represent like components.

### BRIEF DESCRIPTION OF THE DRAWING

FIG. 1 is a schematic of processing equipment according to the present inventive subject matter.

FIG. 2 is another schematic of processing equipment.

FIG. 3 is a perspective view of the pulse heater.

### DETAILED DESCRIPTION

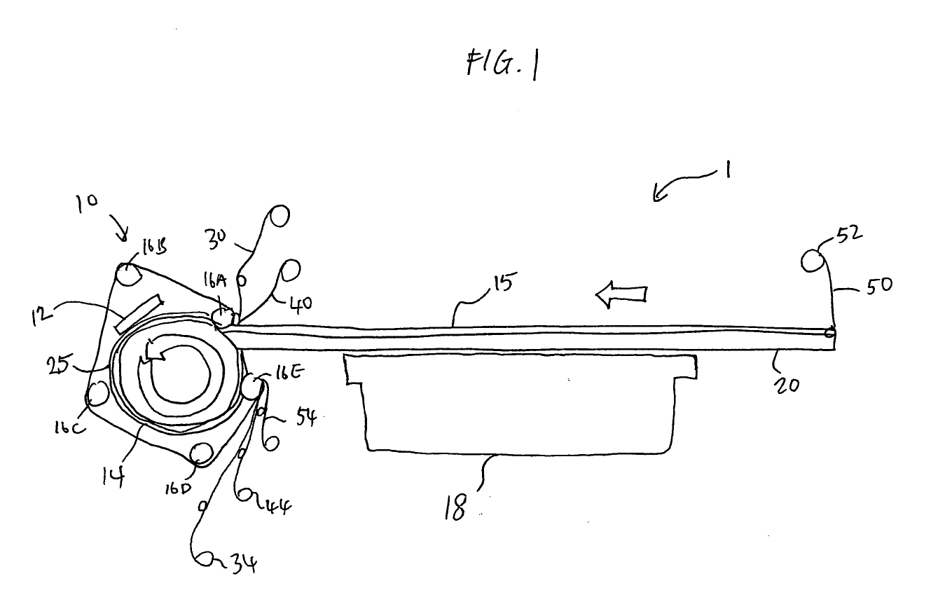

In FIG. 1, processing equipment 1 generally includes rotary heating portion 10, calendar belt 15, one or more pulse heater(s) 18 on work table 20. Positioned on the machine is a continuous work table 20 comprising: tissue 30 with corresponding tissue feed roll 32 and tissue take up roll 34; first donor 40 with corresponding first donor feed roll 42 and first donor take up roll 44; receiver 50 with corresponding receiver feed roll 52 and receiver take up roll 54; and second donor 60 with corresponding second donor feed roll 62 and second donor take up roll 64.

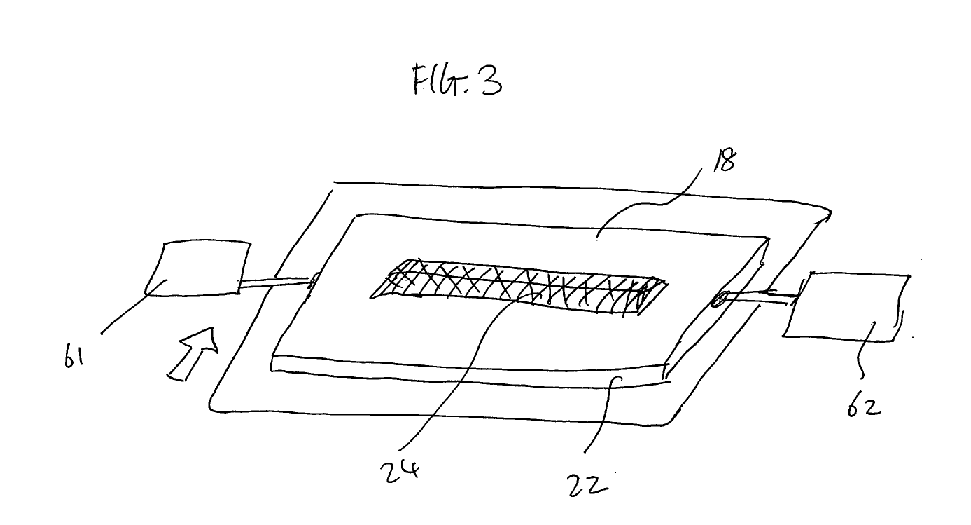

The equipment is preferably operated in a continuous manner, and to that end pulse heater 18 preferably includes pulse heating element 22 and pulse heating vent 24 (as shown in FIG. 3). Pulse heater 18 is positioned on the one side of calendar belt 15, preferably the side away from receiver 50. As the processing equipment 1 operates, receiver feed roll 52 feeds receiver 50 onto calendar belt 15 for printing and dyeing. As calendar belt 15 takes up receiver 50, the temperature of calendar belt is at room temperature or a temperature that is low enough so not to activate the donor. Then as pulse heater 18 starts to operate, it heats one side of calendar belt 15 which, initially combines with the rotary heating portion to create a high total energy pulse, which is consumed by the phase change and reduces by the relative cooling of the calendar drum. Depending on the length of the calendar belt and the speed it operates, the pulse heater's temperature will vary accordingly, but preferably at a temperature of no less than 260° F. However, it is contemplated that a pulse heater can generate as much as 1200° F. depending on the type of receiver that is being preheated. The length of heating of the calendar belt depends on the types of receiver and preferably equal to the length of the time that covers the receiver moving from the belt onto the rotary heating portion. The length of time of pulse heating also depends on the characteristics of the receiver, such as the weight, the density and the heat sync. However, before entering into the rest of the sublimation process, the calendar belt cools down, preferably back to standard sublimation temperature, if not at least to no more than 385° F.

The advantage of using the pulse heater allows for greater use of different dyes. While all sublimation dyes are dispersible, not all dispersed dyes can be sublimated. For example, high energy dyes paired with traditional sublimation process requires a much higher temperature to disperse which can destroy the receiver. The present inventive subject matter uses a pulse heater that breaks the bonds of the high energy dyes and prepares the dispersed side by creating a phase change without reaching the receiver. Thus, as the sublimation process continues, the high energy dyes are dispersed onto the receiver without requiring a higher temperature that can destroy the receiver.

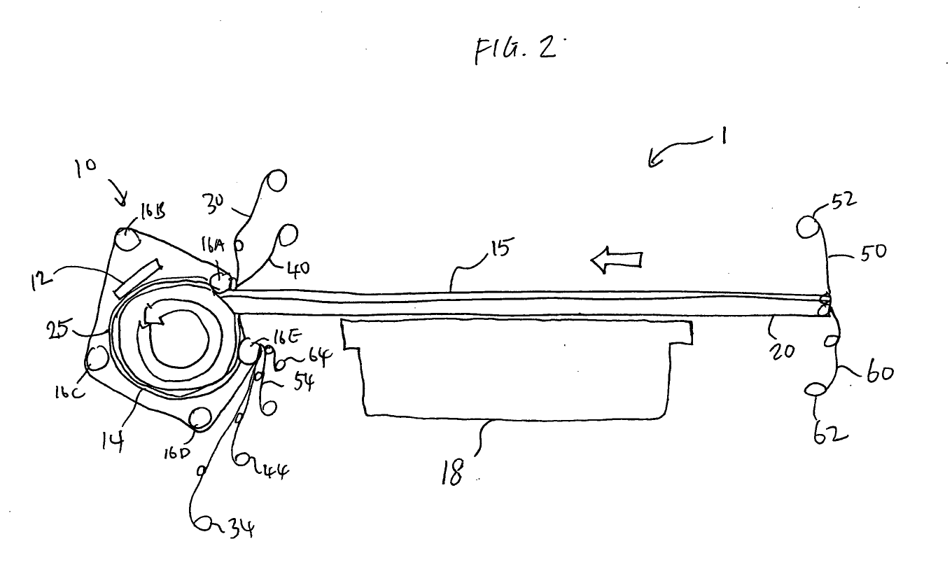

In another preferred embodiment as shown in FIG. 2, besides having a first donor 50 placed on top of calendar belt 15, a second donor 60 taken up by a second donor feed-up roll 62 on the backside of calendar belt 15. As second donor 60 goes through calendar belt 15, pulse heater 18 heats up second donor 60 and prepares for easier ebb and flow of dye and greater saturation and dye coverage without adding excess dye which creates color tint and stability problems in the dyed product. The controlled pulse heat is provided by preheating the calendar belt or the support, which holds the backside or second donor in place. Then by having the front and backside donor goes through the sublimation process simultaneously, this allows printing and dyeing on both side of the receiver without excess bleeding or diffusion on either sides.

Pulse heat can be generated with any conventional heat source. The heat source can be infrared light, UV light, or any other heat source as long as the source adequately heats up the donor to a temperature that allows the donor to be more readily applied to the receiver. Control button 61 is used to control the temperature, the time, and the type of heat generated by the pulse heater. Power source 62 can be connected to just the pulse heater or it can be part of the processing equipment in general.

Once receiver 50 is preheated on the calendar belt by the pulse heater, it goes through rotary heating portion. Rotary heating portion 10 preferably includes a rotary primary heating element 12, a fixed secondary heating element 14, and a heat conductive web 16. The web 16 is positioned by positioners 16A-16E. The rotation speed, configuration and dimensions of the heating portion 10 determine the dwell time of sublimating heat upon the sandwiched work piece of tissue 30, first donor 40, receiver 50, and second donor 60. Dwell time, temperature, and pressure are preferably adjusted by controls (not shown). Despite a current preference for continuous processing, it is also contemplated that embodiments of the inventive subject matter could be practiced in a discontinuous manner, for example with sandwiched work pieces being assembled, and heat and pressure applied in a piece by piece manner. In that regard it is specifically contemplated that the receiver could be cut from a bulk material.

There are existing machines (e.g. Monti Antonio™, Practix™ and other cylinder based machines) that could be modified to operate according to the inventive concepts described herein. One configuration is to have the pulse heater be placed under the calendar belt on the work piece 20 where the pulse heater heats up the receiver on top of the donor. However, another configuration that can also be easily installed is to place a pulse heater on top of the calendar belt, as shown in FIG. 3. Depending on the processing equipment, pulse heater 18 can be placed either under the calendar belt or over the calendar belt, as long as one side of the belt is being preheated. The key aspect is that instead of the calendar belt heated to a normal temperature or even a temperature that is less than 260° F., the calendar belt is heated with the pulse heater to provide additional total energy, that when combined with the drum energy will break up the bonds of the donor dyes for a more saturated sublimation process as it enters into a rotary heating element. Since the receiver is on the other side of the donor, it is not damaged by the high temperature. When a second donor is placed on the opposite side of the calendar belt where the receiver is, the pulse heater also heats up and prepares the second donor to saturate for deeper dye dispersion and penetration. Thus, it is contemplated that heat sufficient to pulse heat would be applied from the two sides of the calendar belt for a length of time that is directly proportional to the length of the belt and the speed at which it operates. Before entering into the rest of the sublimation process, the calendar belt cools down back to normal sublimation temperature. Sublimating heat on any given side is preferably provided for a dwell time of between 40 and 120 seconds, more preferably between 60 and 95 seconds, and most preferably about 75 seconds. Sublimation temperature is preferably no more than 400° F., and more preferably less.

The tissue 30 can be selected from known take up tissues used in the industry. In contrast to the prior art, the tissues are not used in the current embodiments to absorb dyes that pass entirely through the receiver 50 and opposite donor 40 or 60. That is unnecessary because the donor materials are nearly or entirely impermeable to the passage of dyes. Instead the tissue 30 in embodiments of the present invention serve to protect the mechanical parts from excess colorant.

The first and second donors 40, 60 can be selected from known donor papers, or other materials used in the industry. The donor material can be any thin sheet that is substantially impassible to dye from side to side, but which has a surface to which a dye can be temporarily held. Preferably, donors include high energy dyes which provides for more stable and steadfast colors. It should also be appreciated that the terms “dye” and “dyes” are used in the broadest possible sense to include inks, and indeed any chemical composition that can be transferred to a receiving material to color that material. Thus, the terms “dye” and “dyes” include chemical compositions that can change color depending upon temperature or other conditions, and even chemical compositions that are colorless when applied, but turn color upon exposure to moisture, or high temperature.

To that end, donors 40, 60 can be printed with solid colors, or at least relatively large areas of solids and/or large repeating patterns. It is especially contemplated that donors 40, 60 can be printed with solids or large repeating patterns having contiguous areas of at least 10 cm², 50 cm², 100 cm², 200 cm² or 400 cm². To avoid the color shifts that are prevalent with ink jet and other printed donors, it is preferable when printing solids, or patterns including a single color, to use a roller coater (not shown) to ink one or both of the donors 40, 60. By printing both donors 40, 60 in this manner, receivers can be produced that have the same color of solids on both sides, one color of solid on one side and a different color of solid on the other side, a solid on one side and a pattern on the other, and so forth. Printing patterns on both sides is also entirely feasible, although back-to-back registration of the images is still somewhat problematic. Complex patterns and even photographic or other images can also be printed, with third, fourth, and other colors. Indeed, to simplify the drawing, FIG. 1 should be interpreted generically as including all such combinations.

The receiver 50 can be any material that can receive sublimation printing. This includes most especially polyesters and other synthetic polymers that absorb dyes at high temperature and pressure, with currently preferred receiver materials including the true synthetics or non-cellulosics (e.g., polyester, nylon, acrylic, modacrylic, and polyolefin) blends, and so forth. It is contemplated that receiver materials could also include natural fibers (e.g., cotton, wool, silk, linen, hemp, ramie, and jute), semi-synthetics or cellulosics (e.g., vicose rayon and cellulose acetate), but currently available colorants do not “take” very well with such fibers. Receivers can be flexible or rigid, bleached or unbleached, white or colored, woven or non-woven, knitted or non-knitted, or any combination of these or other factors. Thus, a receiver could, for example, include a woven material on one side and a non-woven or different woven material on the other side. Among other things, receivers are contemplated to include fabrics and fibers used for clothing, banners, flags, curtains and other wall coverings, and even carpets.

The advantages of the methods and systems disclosed herein are enormous. First of all, by preheating the calendar belt, the sublimation process generally becomes more advanced. The receiver is not damaged by using higher temperature and thus higher energy dyes can be used. This enables the receiver to be ready to receive dyes. Not only will the dyes and prints be more uniformly and consistently applied, they penetrate deeper into the receiver to reduce bleeding or smudging. The printing and dyeing quality overall is significantly improved.

Furthermore, the pulse heater allows for multiple images or multiple passes to go through on the same receiver without significant registering problems. The different images or dyes will not bleed or interfere with each other with the pulse heater as the pulse heater preps the receiver more efficiently. Consequently, the pulse heater can also generate double-sided printing that is more uniform and consistent in dye dispersion.

Another advantage of the present inventive subject matter is presented in the convenience and ease of installation. The pulse heater can accommodate a variety of DDS machines. This allows flexibility in not having to replace existing machinery and increase costs. Thus, as the quality improves, the overall production costs do not have to increase.

It should be apparent, however, to those skilled in the art that many more modifications besides those already described are possible without departing from the inventive concepts herein. Moreover, in interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps could be present, or utilized, or combined with other elements, components, or steps that are not expressly referenced.

What is claimed is:

1. A method of printing on a receiver;
depositing first and second dyes on first and second donors, respectively;
positioning first and second donors on opposite sides of a receiver;
applying a burst of a pulse energy to the first donor at a temperature of T1; and
applying a heat energy to the receiver at T2.

2. The method of claim 1, wherein T1 is a temperature of at least 260° F.

3. The method of claim 1, wherein T2 is at a temperature substantially lower than T1.

4. The method of claim 1, wherein T1 is applied for at least 3 seconds.

5. The method of claim 1, wherein T1 is applied for a period based upon the pulse energy required for a phase change of the first and second dyes.

6. The method of claim 1, wherein the first donor is physically separate from the second donor.

7. The method of claim 1, further comprising positioning a holder between first donor, receiver.

8. The method of claim 7 wherein the holder is a calendar belt.

9. The method of claim 1, wherein the first donor is a high energy dye.

10. The method of claim 1, wherein T1 is applied based upon a weight of the receiver.

11. The method of claim 1, wherein T1 is applied based upon a density of the receiver.

12. The method of claim 1, wherein the first and second dyes are derived from a same batch of colorant.

13. The method of claim 1, further comprising depositing a third dye on at least one of the first and second donors.

14. The method of claim 1, further comprising depositing a temperature sensitive release agent to the first donor.

15. A sublimation printing device that employs a method according to claim 1.

16. A sublimation printing device that employs a method according to claim 1, further comprising a pre-heating station.

17. An article of clothing manufactured at least in part using a method according to claim 1.
